(19) United States
(12) Patent Application Publication
(10) Pub. No.: US 2026/0026157 A1
(43) Pub. Date: Jan. 22, 2026

(54) DISPLAY DEVICE, ELECTRONIC APPARATUS INCLUDING THE SAME, AND METHOD OF MANUFACTURING DISPLAY DEVICE

(71) Applicant: Samsung Display Co., Ltd., Yongin-si (KR)

(72) Inventors: YOUNGMIN KIM, Yongin-si (KR); GWUI-HYUN PARK, Yongin-si (KR); JONGHEE PARK, Yongin-si (KR); JOONYONG PARK, Yongin-si (KR); HAEIL PARK, Yongin-si (KR); MOONJUNG BAEK, Yongin-si (KR); HEESUNG YANG, Yongin-si (KR); DAEHO LEE, Yongin-si (KR); SUJI HAN, Yongin-si (KR)

(21) Appl. No.: 19/260,944

(22) Filed: Jul. 7, 2025

(30) Foreign Application Priority Data
Jul. 17, 2024 (KR) 10-2024-0094693
Dec. 23, 2024 (KR) 10-2024-0193755

(51) Int. Cl. H10H 29/39; H10H 29/01; H10H 29/37; H10H 29/41; H10H 29/80; H10K 59/12; H10K 59/122; H10K 59/123; H10K 59/124; H10K 59/80

(52) U.S. Cl. CPC H10H 29/39; H10H 29/012; H10H 29/37; H10H 29/41; H10H 29/8325; H10K 59/1201; H10K 59/122; H10K 59/123; H10K 59/124; H10K 59/80518

(57) ABSTRACT

A display device, an electronic apparatus including the display device, and a method for manufacturing the display device are disclosed. The display device may include a connection electrode passing through a base insulating (e.g., electrically insulating) layer and a reflective pattern connected to the connection electrode. The connection electrode may include a first conductive (e.g., electrically conductive) layer and a second conductive (e.g., electrically conductive) layer on the first conductive layer and made of a material different from that of the first conductive layer. The upper surface of the connection electrode may be continuous with the upper surface of the base insulating layer, and the upper surface of the connection electrode and the upper surface of the base insulating layer may substantially form a single plane.

### CROSS-REFERENCE TO RELATED APPLICATIONS

The present application claims priority to and the benefit of Korean Patent Application No. 10-2024-0094693, filed on Jul. 17, 2024, and Korean Patent Application No. 10-2024-0193755, filed on Dec. 23, 2024, in the Korean Intellectual Property Office, the entire contents of both of which are incorporated herein by reference.

### BACKGROUND

### 1. Field

One or more embodiments of the present disclosure relate to a display device including a light-emitting layer, an electronic apparatus including the display device, and a method for manufacturing the display device, and, for example, to a display device with an increased light-emitting region, an electronic apparatus including the display device, and a method for manufacturing a display panel.

### 2. Description of the Related Art

One or more types (kinds) of electronic apparatuses have been and/or are being developed. Electronic apparatuses include display devices that provide information to users.

Among electronic apparatuses, wearable electronic apparatuses that can be worn on the human body are being developed. An example of a wearable electronic apparatus is a device that can be mounted on a user's head, such as a head-mounted device (HMD). Devices like the HMDs requires (or should have) high resolution. To increase or enhance resolution, a design that improve or enhance light-emitting efficiency is desired or required.

### SUMMARY

One or more aspects of embodiments of the present disclosure are directed toward a display device having improved or enhanced light-emitting efficiency and/or light output efficiency.

One or more aspects of embodiments of the present disclosure are directed toward an electronic apparatus including the display device.

One or more aspects of embodiments of the present disclosure are directed toward a method for manufacturing the display device.

Additional aspects of embodiments will be set forth in part in the description which follows and, in part, will be apparent from the description or may be learned by practice of the presented embodiments of the disclosure.

One or more embodiments of the present disclosure provide a display device including a base layer, a transistor on the base layer, a base insulating (e.g., electrically insulating) layer arranged on the transistor, a connection electrode electrically connected to the transistor, passing through the base insulating layer, and including a first conductive (e.g., electrically conductive) layer and a second conductive (e.g., electrically conductive) layer on the first conductive layer and having a material different from that of the first conductive layer, a light-emitting element on the base insulating layer and connected to the connection electrode, and at least one passivation layer on the base insulating layer. The light-emitting element includes a reflective pattern in contact with the connection electrode, a first electrode on the reflective pattern, a light-emitting unit on the first electrode, and a second electrode on the light-emitting unit. The at least one passivation layer is between the first electrode and the reflective pattern, the first electrode is connected to the reflective pattern through a contact hole passing through the at least one passivation layer. An upper surface of the connection electrode is continuous with an upper surface of the base insulating layer, and the upper surface of the connection electrode and the upper surface of the base insulating layer substantially form a single plane.

In one or more embodiments of the present disclosure, a display device may further include a pixel define layer on the first electrode and the at least one passivation layer and having an opening defined therein and exposing at least a portion of the first electrode.

In one or more embodiments, the connection electrode may overlap the opening.

In one or more embodiments, the contact hole may overlap the pixel define layer.

In one or more embodiments, the second conductive layer may have a smaller area than that of the first conductive layer on a plane (e.g., in plan view).

In one or more embodiments, a width measured at an upper surface of the second conductive layer may be smaller than a width measured at a lower surface of the second conductive layer.

In one or more embodiments, the base insulating layer may be a single-layer organic layer, and the at least one passivation layer may include an inorganic layer.

In one or more embodiments, the first conductive layer may include a metal, and the second conductive layer may include a metal oxide.

In one or more embodiments, the second conductive layer may be thicker than the first conductive layer.

In one or more embodiments, the light-emitting element may include a first light-emitting element that is configured or arranged to generate a first color light and a second light-emitting element that is configured or arranged to generate a second color light having a longer wavelength than the first color light. The at least one passivation layer may include a first passivation layer and a second passivation layer. The first passivation layer may be between the first electrode of the first light-emitting element and the reflective pattern of the first light-emitting element. The first passivation layer and the second passivation layer may be between the first electrode of the second light-emitting element and the reflective pattern of the second light-emitting element.

In one or more embodiments, the light-emitting unit of the first light-emitting element and the light-emitting unit of the second light-emitting element may have an integrated shape (e.g., may be combined into a single, cohesive form or have a monolithic shape).

In one or more embodiments, the light-emitting unit may include a first light-emitting layer configured or arranged to generate a first color light, a first charge generation layer on the first light-emitting layer, a second light-emitting layer on the first charge generation layer and configured or arranged to generate a second color light, a second charge generation layer on the second light-emitting layer, and a third light-emitting layer on the second charge generation layer and configured or arranged to generate a third color light.

In one or more embodiments of the present disclosure, a display device may further include a thin film encapsulation layer configured or arranged to cover the light-emitting element and a color filter on the thin film encapsulation layer to overlap the light-emitting element.

In one or more embodiments of the present disclosure, a display device may further include a lower connection electrode electrically connecting the transistor and the connection electrode and located or arranged below the base insulating layer. In one or more embodiments, the base layer may include a glass substrate.

In one or more embodiments of the present disclosure, an electronic apparatus includes a display device and a frame configured or arranged to accommodate the display device. The display device includes a transistor, a base insulating (e.g., electrically insulating) layer on the transistor, a connection electrode electrically connected to the transistor, passing through the base insulating layer, and including a first conductive (e.g., electrically conductive) layer and a second conductive (e.g., electrically conductive) layer on the first conductive layer and having a material different from that of the first conductive layer, a light-emitting element on the base insulating layer and connected to the connection electrode, and at least one passivation layer on the base insulating layer. The light-emitting element includes a reflective pattern, a first electrode on the reflective pattern, a light-emitting unit on the first electrode, and a second electrode on the light-emitting unit. The at least one passivation layer is between the first electrode and the reflective pattern, and the first electrode is connected to the reflective pattern through a contact hole passing through the at least one passivation layer. An upper surface of the connection electrode is continuous with an upper surface of the base insulating layer, and the upper surface of the connection electrode and the upper surface of the base insulating layer substantially form a single plane.

In one or more embodiments, the electronic apparatus may be a virtual reality (VR) terminal.

In one or more embodiments of the present disclosure, a method for manufacturing a display device includes: forming or arranging a first conductive (e.g., electrically conductive) pattern on a base layer; forming or arranging a second conductive (e.g., electrically conductive) pattern including a material different from that of the first conductive pattern on the first conductive pattern; forming or arranging a preliminary base insulating (e.g., electrically insulating) layer to cover the second conductive pattern; polishing the preliminary base insulating layer to form or arrange a base insulating (e.g., electrically insulating) layer that exposes an upper surface of the second conductive pattern; forming or arranging a reflective pattern connected to the second conductive pattern on the base insulating layer; forming or arranging at least one passivation layer covering the reflective pattern on the base insulating layer; forming or arranging a first electrode connected to the reflective pattern through a contact hole passing through the at least one passivation layer on the at least one passivation layer; forming or arranging a light-emitting unit on the first electrode; and forming or arranging a second electrode on the light-emitting unit. An upper surface of the connection electrode is continuous with an upper surface of the base insulating layer, and the upper surface of the connection electrode and the upper surface of the base insulating layer substantially form a single plane.

In one or more embodiments, on a plane (e.g., in plan view), the second conductive pattern may have a smaller area than that of the first conductive pattern.

In one or more embodiments, a width measured at the upper surface of the second conductive pattern may be smaller than a width measured at the lower surface of the second conductive pattern.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1A is a block diagram of an electronic apparatus according to one or more embodiments of the present disclosure;

FIG. 1B is an exploded perspective view of the electronic apparatus according to one or more embodiments of the present disclosure;

FIG. 2A is a perspective view of a display panel according to one or more embodiments of the present disclosure;

FIG. 2B is a plan view of the display panel according to one or more embodiments of the present disclosure;

FIG. 2C is a cross-sectional view of the display panel according to one or more embodiments of the present disclosure;

FIG. 2D is an enlarged view of a portion of FIG. 20;

FIG. 3 is an enlarged cross-sectional view of a light-emitting unit according to one or more embodiments of the present disclosure; and

FIGS. 4-12 are cross-sectional views illustrating a method for manufacturing a display panel according to one or more embodiments of the present disclosure.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the accompanying drawings and the written description, and duplicative descriptions thereof may not be provided in the specification.

In the present disclosure, it will be understood that if (e.g., when) an element (or a region, a layer, a portion, and/or the like) is referred to as being “on”, “connected to”, or “coupled to” another element, it may be directly on, directly connected, or directly coupled to the other element, or intervening elements may be present therebetween. In contrast, if (e.g., when) an element is referred to as being “directly on”, “directly connected to”, or “directly coupled to” another element, there are no intervening elements present therebetween.

In the accompanying drawings, the thicknesses, ratios, and dimensions of elements may be exaggerated for effective description of the technical contents.

As used herein, the term “and/or” includes any and all combinations that the associated configurations may define.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

Throughout the present disclosure, the expression “at least one of a, b, or c” or “at least one selected from among a, b, and c” indicates only a, only b, only c, both (e.g., simultaneously) a and b, both (e.g., simultaneously) a and c, both (e.g., simultaneously) b and c, all of a, b, and c, or variations thereof.

Although the terms “first”, “second”, and/or the like may be used herein to describe one or more suitable components, these components should not be limited by these terms. These terms are used only to distinguish one component, part, region, layer, or portion from another component, part, region, layer, or portion. For example, without departing from the scope of the present disclosure, a first component, a first part, a first region, a first layer, or a first portion may be referred to as a second component, a second part, a second region, a second layer, or a second portion, and similarly, a second component, a second part, a second region, a second layer, or a second portion may also be referred to as a first component, a first part, a first region, a first layer, or a first portion.

Singular expressions include plural expressions unless the context clearly indicates otherwise.

The terms, such as “below”, “lower”, “above”, “upper”, and/or the like are used herein for ease of description to describe one element's relation to another element(s) as illustrated in the drawings. The above terms are relative concepts and are described based on the directions indicated in the drawings.

It will be understood that the terms “include”, “including”, “have”, and/or “having”, if (e.g., when) used in this specification, specify the presence of stated features, integers, steps, operations, elements, components, and/or groups thereof, but do not preclude the presence or addition of one or more other features, integers, steps, operations, elements, components, and/or groups thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise defined, all terms (including technical and scientific terms) used herein have substantially the same meaning as generally understood by one of ordinary skill in the art to which this disclosure belongs. It will be further understood that terms, such as those defined in generally used dictionaries, should be interpreted as having a meaning that is consistent with their meaning in the context of the relevant art and will not be interpreted in an idealized or overly formal sense unless expressly so defined herein.

In the context of the present disclosure and unless otherwise defined, a plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

Hereinafter, one or more embodiments of the present disclosure will be described in more detail with reference to the drawings.

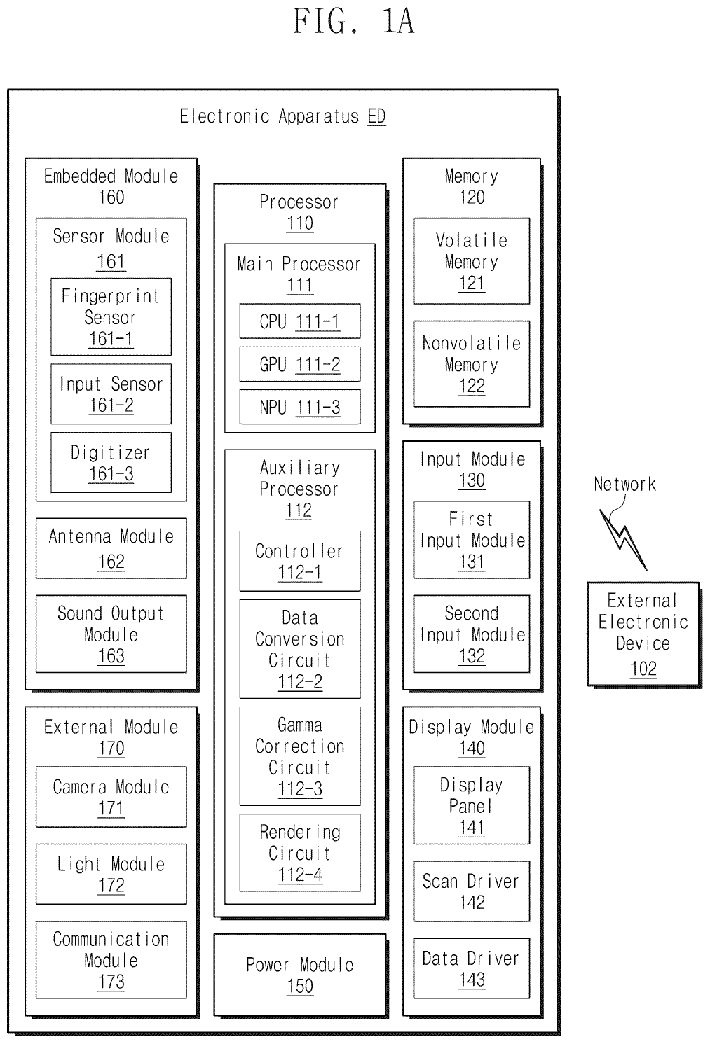

FIG. 1A is a block diagram of an electronic apparatus ED according to one or more embodiments of the present disclosure. FIG. 1B is an exploded perspective view of the electronic apparatus ED according to one or more embodiments of the present disclosure.

The electronic apparatus ED according to one or more embodiments of the present disclosure may include a display device 140. As illustrated in FIG. 1A, the electronic apparatus ED may be to output one or more suitable information through the display device 140 in an operating system. If (e.g., when) a processor 110 executes an application stored in a memory 120, the display device 140 may provide application information to a user through a display panel 141.

The processor 110 may be to obtain an external input through an input module 130 or a sensor module 161 and execute an application corresponding to the external input. For example, if (e.g., when) a user selects a camera icon displayed on the display panel 141, the processor 110 may obtain an input from the user through an input sensor 161-2 and activate a camera module 171. The processor 110 may be to transmit image data, which correspond to a captured image obtained through the camera module 171, to the display device 140. The display device 140 may be to display an image corresponding to the captured image through the display panel 141.

As another example, if (e.g., when) personal information authentication is executed in the display device 140, a fingerprint sensor 161-1 may obtain input fingerprint information as input data. The processor 110 may be to compare the input data obtained through the fingerprint sensor 161-1 with the authentication data stored in the memory 120 and execute an application according to the result of the comparison. The display device 140 may be to display the information executed according to the logic of the application through the display panel 141.

As another example, if (e.g., when) a music streaming icon displayed on the display device 140 is selected, the processor 110 may obtain a user input through the input sensor 161-2 and activate a music streaming application stored in the memory 120. If (e.g., when) a music execution command is input in the music streaming application, the processor 110 may activate an audio output module 163 and provide the user with audio information corresponding to the music execution command.

In one or more embodiments, the operation of the electronic apparatus ED has been briefly described in more detail. Hereinafter, the configuration or arrangement of the electronic apparatus ED will be described in more detail. One or more of the components of the electronic apparatus ED as described in more detail herein may be integrated and provided as one component, and one component may be provided by being separated into two or more components.

Referring to FIG. 1A, the electronic apparatus ED may be to communicate with an external electronic apparatus 102 via a network (e.g., a short-range wireless communication network or a long-range wireless communication network). According to one or more embodiments of the present disclosure, the electronic apparatus ED may include a processor 110, a memory 120, an input module 130, a display device 140, a power module 150, an embedded module 160, and an external module 170. According to one or more embodiments of the present disclosure, in the electronic apparatus ED, at least one selected from among the components as described in one or more embodiments may not be provided, or one or more other components may be added. According to one or more embodiments of the present disclosure, one or more (e.g., the sensor module 161, an antenna module 162, or the audio output module 163) selected from among the components as described in one or more embodiments may be integrated into another component (e.g., the display device 140).

The processor 110 may be to execute software to control at least one other component (e.g., a hardware component and/or a software component) of the electronic apparatus ED connected to the processor 110 and perform one or more suitable data processing or operations. According to one or more embodiments of the present disclosure, as at least part of the data processing or operations, the processor 110 may be to store commands or data received from other components (e.g., the input module 130, the sensor module 161, or a communication module 173) in volatile memory 121, process the commands or data stored in the volatile memory 121, and store resulting data in non-volatile memory 122.

The processor 110 may include a main processor 111 and an auxiliary processor 112. The main processor 111 may include one or more selected from a central processing unit (CPU) 111-1 or an application processor (AP). The main processor 111 may further include one or more selected from among a graphic processing unit (GPU) 111-2, a communication processor (CP), and an image signal processor (ISP).

The auxiliary processor 112 may include a controller 112-1. The controller 112-1 may include an interface conversion circuit and a timing control circuit. The controller 112-1 may be to receive an image signal from the main processor 111, convert the data format of the image signal to match the interface specifications of the display device 140, and output image data. The controller 112-1 may be to output one or more suitable control signals desired or necessary to drive the display device 140.

The auxiliary processor 112 may further include a data conversion circuit 112-2, a gamma correction circuit 112-3, a rendering circuit 112-4, and/or the like. The data conversion circuit 112-2 may be to receive image data from the controller 112-1 and compensate for the image data so that an image is displayed at a desired or suitable brightness according to the characteristics of the electronic apparatus ED or user settings or may be to convert the image data to reduce power consumption or compensate for afterimages and/or the like. The gamma correction circuit 112-3 may be to convert image data, a gamma reference voltage, and/or the like so that an image displayed on the electronic apparatus ED has desired or suitable gamma characteristics. The rendering circuit 112-4 may be to receive image data from the controller 112-1 and render the image data by considering the pixel arrangement and/or the like of the display panel 141 applied to the electronic apparatus ED. The memory 120 may be to store one or more suitable data used by at least one component of the electronic apparatus ED (e.g., the processor 110 or the sensor module 161) and input data or output data for commands related thereto. The memory 120 may include at least one selected from the volatile memory 121 and the non-volatile memory 122.

The input module 130 may be to receive commands or data, which are used for the components of the electronic apparatus ED (e.g., the processor 110, the sensor module 161, or the audio output module 163), from the outside of the electronic apparatus ED (e.g., a user or the external electronic apparatus 102).

The input module 130 may include a first input module 131 into which commands or data are input from a user and a second input module 132 into which commands or data are input from the external electronic apparatus 102.

The display device 140 may be to visually provide information to a user. The display device 140 may include a display panel 141, a scan driver 142, and a data driver 143. The display device 140 may further include a window, a chassis, a bracket, and/or a housing to protect the display panel 141.

The display panel 141 may include an organic light-emitting display panel or an inorganic light-emitting display panel, and the type (kind) of the display panel 141 is not particularly limited thereto. The display panel 141 may be a rigid type (kind) or a flexible type (kind) that may be rolled or folded. The display device 140 may further include a heat dissipation member, a bracket, or a supporter that is to support the display panel 141.

The scan driver 142 may be mounted on the display panel 141 as a driving chip. In one or more embodiments, the scan driver 142 may be integrated into the display panel 141. The scan driver 142 may be receive a control signal from the controller 112-1 and output scan signals to the display panel 141 in response to the control signal.

The display panel 141 may further include a light-emitting driver. The light-emitting driver may be to output a light-emitting control signal to the display panel 141 in response to a control signal received from the controller 112-1. The light-emitting driver may be formed or arranged separately from the scan driver 142 or may be integrated into the scan driver 142.

The data driver 143 may be to receive a control signal from the controller 112-1, convert image data into an analog voltage (e.g., a data voltage) in response to the control signal, and then output data voltages to the display panel 141.

The display device 140 may further include a light-emitting driver and a voltage generation circuit. The voltage generation circuit may be to output one or more suitable voltages desired or required to drive the display panel 141.

The power module 150 may be to supply power to the components of the electronic apparatus ED. The power module 150 may include a battery to charge a power voltage. The battery may include a non-rechargeable primary battery, a rechargeable secondary battery, or a fuel cell.

The electronic apparatus ED may further include an embedded module 160 and an external module 170. The embedded module 160 may include a sensor module 161, an antenna module 162, and an audio output module 163. The external module 170 may include a camera module 171, a light module 172, and a communication module 173.

The sensor module 161 may be to sense an input by a body part of a user or an input by a pen among the first input modules 131 and generate an electrical signal or a data value corresponding to the input. The sensor module 161 may include at least any one of a fingerprint sensor 161-1, an input sensor 161-2, or a digitizer 161-3.

The fingerprint sensor 161-1 may be to generate a data value corresponding to a user's fingerprint. The fingerprint sensor 161-1 may include either an optical fingerprint sensor and/or a capacitive fingerprint sensor.

The input sensor 161-2 may be to generate a data value corresponding to the coordinate information of an input by a body part of a user and/or an input by a pen. The input sensor 161-2 may be to generate the data value based on the amount of change in capacitance caused by the input. The input sensor 161-2 may be to sense an input by a passive pen or transmit/receive data to/from an active pen.

The digitizer 161-3 may be to generate a data value corresponding to the coordinate information of an input by a pen. The digitizer 161-3 may be to generate the data value based on the amount of change in electromagnetic force caused by the input. The digitizer 161-3 may be to sense an input by a passive pen or transmit/receive data to/from an active pen.

At least one of the fingerprint sensor 161-1, the input sensor 161-2, or the digitizer 161-3 may be implemented as a sensor layer formed or arranged on the display panel 141 through a continuous process. The fingerprint sensor 161-1, the input sensor 161-2, and the digitizer 161-3 may be located or arranged on the upper side of the display panel 141, and any one selected from among the fingerprint sensor 161-1, the input sensor 161-2, and the digitizer 161-3, for example, the digitizer 161-3, may be arranged on the lower side of the display panel 141.

At least two or more of the fingerprint sensor 161-1, the input sensor 161-2, or the digitizer 161-3 may be formed or arranged to be integrated into one sensing panel through substantially the same process. If (e.g., when) integrated into one sensing panel, the sensing panel may be arranged between the display panel 141 and the window arranged on the upper side of the display panel 141. According to one or more embodiments of the present disclosure, the sensing panel may be arranged on the window, and the position of the sensing panel is not particularly limited thereto.

At least one of the fingerprint sensor 161-1, the input sensor 161-2, or the digitizer 161-3 may be embedded in the display panel 141. For example, at least one selected from among the fingerprint sensor 161-1, the input sensor 161-2, and the digitizer 161-3 may be formed concurrently (e.g., simultaneously) through a process of forming elements (e.g., light-emitting elements, transistors, and/or the like) included in the display panel 141.

In one or more embodiments, the sensor module 161 may be to generate an electrical signal or a data value corresponding to an internal state or an external state of the electronic apparatus ED. The sensor module 161 may further include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 162 may include one or more antennas to transmit or receive a signal or power to or from the outside. According to one or more embodiments of the present disclosure, the communication module 173 may be to transmit a signal to an external electronic apparatus or receive a signal from an external electronic apparatus through an antenna suitable for a communication method. The antenna pattern of the antenna module 162 may be integrated into one component (e.g., the display panel 141) of the display device 140, the input sensor 161-2, and/or the like.

The audio output module 163 may be a device to output an audio signal to the outside of the electronic apparatus ED.

The camera module 171 may be to capture still images and/or moving images. According to one or more embodiments of the present disclosure, the camera module 171 may include one or more lenses, an image sensor, or an image signal processor. The camera module 171 may further include an infrared camera capable of measuring the presence, position, gaze, and/or the like of a user.

The light module 172 may be to provide light. The light module 172 may include a light-emitting diode and/or a xenon lamp. The light module 172 may be to operate in conjunction with the camera module 171 or independently.

The communication module 173 may be to support the establishment of a wired or wireless communication channel between the electronic apparatus ED and the external electronic apparatus 102 and the performance of communication through the established communication channel. The input module 130, the sensor module 161, the camera module 171, and/or the like may be utilized to control the operation of the display device 140 in conjunction with the processor 110.

The processor 110 may be to output commands or data to the display device 140, the audio output module 163, the camera module 171, or the light module 172, based on input data received from the input module 130. For example, the processor 110 may be to generate image data in response to the input data applied through a mouse, an active pen, and/or the like and output the image data to the display device 140 or generate command data in response to the input data and output the command data to the camera module 171 or the light module 172.

The electronic apparatus ED according to one or more embodiments of the present disclosure may take one or more suitable types (kinds) or forms. The electronic apparatus ED may include, for example, at least one of a portable communication device (e.g., a smart phone), a tablet device, a portable multimedia device, a wearable device, or an electric home appliance. The electronic apparatus ED according to one or more embodiments of the present disclosure is not limited to the devices as described in one or more embodiments. Depending on the type (kind) or form of the electronic apparatus ED, one or more of the components of the electronic apparatus ED as described with reference to FIG. 1A may not be provided. Hereinafter, the display panel 141 of FIG. 1A will be described in more detail as a display panel DP.

FIG. 1B illustrates a virtual reality headset (or head-mounted device) as an example of a wearable device. In one or more embodiments, the virtual reality headset may include a see-through type (kind) that provides augmented reality (AR) based on actual external objects and a see-closed type (kind) that provides virtual reality (VR) to a user with a screen independent of external objects.

Referring to FIG. 1B, the electronic apparatus ED may include a display panel DP and a lens unit LS opposite to (e.g., facing) the display panel DP. In one or more embodiments, the electronic apparatus ED may include a frame FR to accommodate the display panel DP and the lens unit LS. The frame FR may include a main frame MF and a cover frame CFR. A fixing member FP may be coupled to the main frame MF and may be worn on a user's head.

The cover frame CFR may be coupled to the main frame MF, and the lens unit LS and the display panel DP may be arranged in a space between the cover frame CFR and the main frame MF. The main frame MF may provide a space in which the lens unit LS and the display panel DP may be stored.

If (e.g., when) a user wears the headset, the lens unit LS may be between the display panel DP and the user. The lens unit LS may be to pass an image generated by the display panel DP through and provide the image to the user. For example, the lens unit LS may include one or more suitable types (kinds) of lenses, such as a multi-channel lens, a convex lens, a concave lens, a spherical lens, an aspherical lens, a single lens, a compound lens, a standard lens, a narrow-angle lens, a wide-angle lens, a fixed-focus lens, and/or a variable-focus lens. The lens unit LS may include a first lens LS1 and a second lens LS2. The first lens LS1 and the second lens LS2 may be positioned to correspond to the positions of the user's left and right eyes. For example, if (e.g., when) a user wears the headset, the lens unit LS is positioned between the display panel DP and the user. The lens unit LS passes the image generated by the display panel DP to the user. It may include various types of lenses, such as multi-channel, convex, concave, spherical, aspherical, single, compound, standard, narrow-angle, wide-angle, fixed-focus, and/or variable-focus lenses. The lens unit may be composed of a first lens LS1 and a second lens LS2, corresponding to the user's left and right eyes.

The display panel DP may be fixedly connected to the main frame MF or may be detachably connected thereto. The display panel DP will be described in more detail herein.

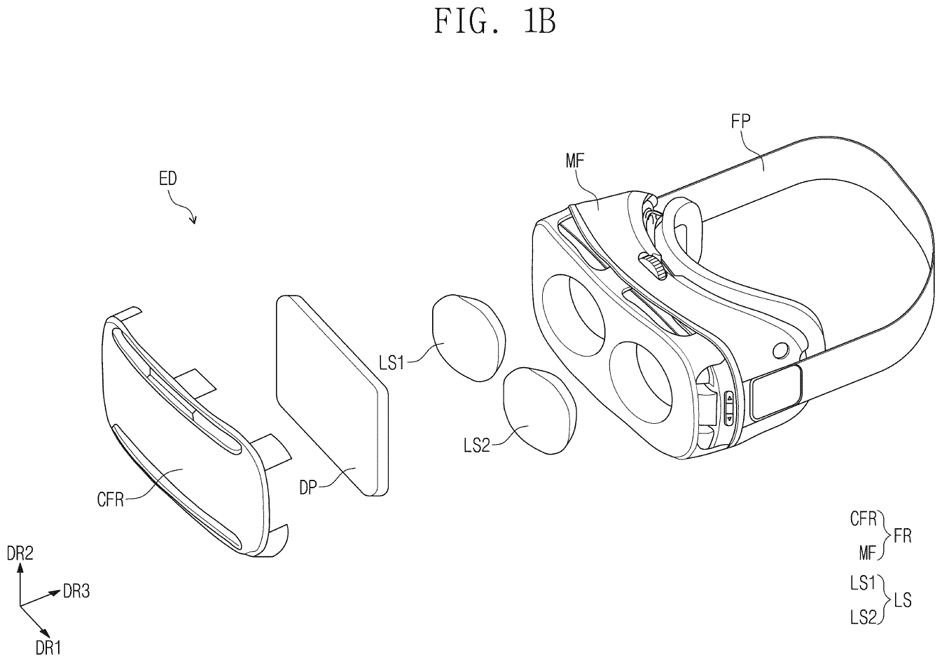

FIG. 2A is a perspective view of a display panel DP according to one or more embodiments of the present disclosure. FIG. 2B is a plan view of the display panel DP according to one or more embodiments of the present disclosure. FIG. 2C is a cross-sectional view of the display panel DP according to one or more embodiments of the present disclosure. FIG. 2D is an enlarged view of a portion of FIG. 2C.

Referring to FIG. 2A, the display panel DP may include a display region AA and a peripheral region NAA. The peripheral region NAA may be around (e.g., surround) the display region AA. Pixels may be arranged in the display region AA, and pixels may not be arranged in the peripheral region NAA.

FIG. 2B is an enlarged view of the display region AA. The display region AA may include a first light-emitting region PXA-1, a second light-emitting region PXA-2, and a third light-emitting region PXA-3. Each of the first light-emitting region PXA-1, the second light-emitting region PXA-2, and the third light-emitting region PXA-3 may be provided in plurality, and the first light-emitting regions PXA-1, the second light-emitting regions PXA-2, and the third light-emitting regions PXA-3 may be arranged according to a specific (e.g., set or predetermined) rule. The display region AA may further include a non-light-emitting region NPXA defining a boundary region of the first light-emitting region PXA-1, the second light-emitting region PXA-2, and the third light-emitting region PXA-3 around the first light-emitting region PXA-1, the second light-emitting region PXA-2, and the third light-emitting region PXA-3.

In the display region AA, pixels may be arranged to respectively correspond to the first light-emitting region PXA-1, the second light-emitting region PXA-2, and the third light-emitting region PXA-3. The pixels may include light-emitting elements. FIG. 2B illustrates first electrodes AE of the light-emitting elements arranged in the first light-emitting region PXA-1, the second light-emitting region PXA-2, and the third light-emitting region PXA-3.

The first light-emitting region PXA-1, the second light-emitting region PXA-2, and the third light-emitting region PXA-3 may be to provide light of different wavelengths (or light of different peak wavelengths) to the outside. The first light-emitting region PXA-1 may be to emit a first color light as primary light, and the second light-emitting region PXA-2 may be to emit a second color light different from the first color light as primary light. The third light-emitting region PXA-3 may be to emit a third color light (primary light) of a wavelength different from those of the first color light and the second color light.

Among the first light-emitting region PXA-1, the second light-emitting region PXA-2, and the third light-emitting region PXA-3, the third light-emitting region PXA-3 may have the largest area, and the second light-emitting region PXA-2 may have the smallest area. However, this is an example, and the comparison of the areas of the first to third light-emitting regions PXA-1, PXA-2, and PXA-3 is not limited thereto. In one or more embodiments, the first color light may be blue light, the second color light may be green light, and the third color light may be red light, but embodiments of the present disclosure are not necessarily limited thereto. The areas of the first and third light-emitting regions PXA-1 and PXA-3 may be substantially the same as each other.

In FIG. 2B, the first light-emitting region PXA-1, the second light-emitting region PXA-2, and the third light-emitting region PXA-3 are arranged along one direction. The one direction may be the horizontal direction of FIG. 2B, which may be the first direction DR1 or the second direction DR2 of FIG. 2A. The first light-emitting region PXA-1, the second light-emitting region PXA-2, and the third light-emitting region PXA-3 arranged continuously or adjacently may be defined as a unit region, and unit regions may be repeatedly arranged within a pixel row PXR.

The first light-emitting region PXA-1, the second light-emitting region PXA-2, and the third light-emitting region PXA-3 arranged within the closest pixel rows PXR may not be aligned with each other in a direction that crosses the one direction, but may be arranged to be staggered from each other. For example, between the second light-emitting region PXA-2 and the third light-emitting region PXA-3 arranged within one pixel row PXR, the first light-emitting region PXA-1 of an adjacent pixel row PXR may be arranged.

The light-emitting regions PXA-1, PXA-2, and PXA-3 of odd-numbered pixel rows PXR may be aligned with each other along a direction that crosses the one direction, and the light-emitting regions PXA-1, PXA-2, and PXA-3 of even-numbered pixel rows PXR may be aligned with each other along a direction that crosses the one direction.

Referring to FIG. 2C, the display panel DP may include a base layer BS, a driving element layer DP-CL arranged on the base layer BS, a display element layer DP-LD arranged on the driving element layer DP-CL, and an encapsulation layer TFE arranged on the display element layer DP-LD. In one or more embodiments, the display panel DP may further include a color filter layer CFL arranged on the encapsulation layer TFE.

The base layer BS may include a glass substrate and/or a synthetic resin substrate. The driving element layer DP-CL may include pixel circuits arranged in the first to third light-emitting regions PXA-1, PXA-2, and PXA-3, respectively. In FIG. 2C, one transistor 100PC included in a pixel circuit is illustrated as an example.

A first insulating layer 10 may be arranged on an upper surface of the base layer BS. The first insulating layer 10 may include a barrier layer or a buffer layer. The first insulating layer 10 may prevent moisture from penetrating (or reduce a degree to or occurrence of which moisture penetrates) the base layer BS from the lower side to the upper side and improve or enhance bonding strength to semiconductor patterns SC, AL, DR, and SCL. The first insulating layer 10 may include a plurality of insulating (e.g., electrically insulating) layers. The first insulating layer 10 may include at least one of silicon oxide, silicon nitride, or silicon oxynitride. For example, the first insulating layer 10 may include a structure in which a silicon oxide layer and a silicon nitride layer are alternately stacked.

The semiconductor patterns SC, AL, DR, and SCL may be arranged on the first insulating layer 10. The semiconductor patterns SC, AL, DR, and SCL may include polysilicon. However, the semiconductor patterns SC, AL, DR, and SCL are not limited thereto and may include amorphous (e.g., non-crystalline) silicon, low-temperature polycrystalline silicon, and/or oxide semiconductor.

FIG. 2C only illustrates one or more of the semiconductor patterns SC, AL, DR, and SCL, and additional semiconductor patterns SC, AL, DR, and SCL may be arranged in other regions on a plane (e.g., in plan view). The semiconductor patterns SC, AL, DR, and SCL may be arranged in a specific (e.g., set or predetermined) rule across the first to third light-emitting regions PXA-1, PXA-2, and PXA-3 of FIG. 2B.

The semiconductor patterns SC, AL, DR, and SCL may have different doping levels depending on regions and may have different electrical properties depending on the doping levels. The semiconductor patterns SC, AL, DR, and SCL may include a first region SC, DR, and SCL with high conductivity (e.g., electrical conductivity) and a second region AL with low conductivity (e.g., electrical conductivity). The first region SC, DR, and SCL may be doped with a negative type (kind) dopant (or an N-type (kind) dopant) or a positive type (kind) dopant (or a P-type (kind) dopant). A P-type (kind) transistor may include a doped region doped with the P-type (kind) dopant, and an N-type (kind) transistor may include a doped region doped with the N-type (kind) dopant. The second region AL may be an undoped region or a region doped with a lower concentration than the first region SC, DR, and SCL.

The conductivity (e.g., electrical conductivity) of the first region SC, DR, and SCL may be greater than that of the second region AL and may substantially function as an electrode or a signal line. The second region AL may substantially correspond to an active region AL (or channel) of the transistor 100PC. For example, the second region AL of the semiconductor patterns SC, AL, DR, and SCL may be the active region AL of the transistor 100PC, another portion SC or DR thereof may be a source region SC or a drain region DR of the transistor 100PC, and still another portion SCL thereof may be a connection electrode or a connection signal line SCL.

FIG. 2C illustrates a portion of the connection signal line SCL formed or arranged from the semiconductor patterns SC, AL, DR, and SCL. In one or more embodiments, the connection signal line SCL may be electrically connected to the drain region DR of the transistor 100PC on a plane (e.g., in plan view).

A second insulating layer 20 may be arranged on the first insulating layer 10. The second insulating layer 20 may commonly overlap the first to third light-emitting regions PXA-1, PXA-2, and PXA-3 and the non-light-emitting region NPXA (see FIG. 2B) and may cover the semiconductor patterns SC, AL, DR, and SCL. The second insulating layer 20 may be an inorganic layer and/or an organic layer and have a single-layer structure or a multi-layer structure. The second insulating layer 20 may include at least one of aluminum oxide, titanium oxide, silicon oxide, silicon nitride, silicon oxynitride, zirconium oxide, or hafnium oxide.

In one or more embodiments, the second insulating layer 20 may be a single-layer silicon oxide layer. Unless otherwise described herein, the insulating (e.g., electrically insulating) layer of the driving element layer DP-CL to be described in more detail in one or more embodiments may be an inorganic layer or an organic layer and have a single-layer structure or a multi-layer structure. The inorganic layer may include at least one of aluminum oxide, titanium oxide, silicon oxide, silicon nitride, silicon oxynitride, zirconium oxide, or hafnium oxide, but embodiments of the present disclosure are not limited thereto.

A gate GT of the transistor 100PC may be arranged on the second insulating layer 20. The gate GT may be a portion of a metal pattern. The gate GT may overlap the active region AL. In a process of doping or reducing the semiconductor patterns SC, AL, DR, and SCL, the gate GT may function as a mask.

A third insulating layer 30 may be arranged on the second insulating layer 20 and may cover the gate GT. The third insulating layer 30 may commonly overlap the first to third light-emitting regions PXA-1, PXA-2, and PXA-3 and the non-light-emitting region NPXA. The third insulating layer 30 may be an inorganic layer.

A fourth insulating layer 40 may be arranged on the third insulating layer 30. The fourth insulating layer 40 may be an inorganic layer. A first connection electrode CNE1 may be arranged on the fourth insulating layer 40. The first connection electrode CNE1 may be connected to the connection signal line SCL through a first contact hole CNT1 passing through the first, second, third, and fourth insulating layers 10, 20, 30, and 40.

As illustrated in FIGS. 2C and 2D, a fifth insulating layer 50 may be arranged on the fourth insulating layer 40. The fifth insulating layer 50 may be an inorganic layer. A second connection electrode CNE2 may be arranged on the fifth insulating layer 50. In one or more embodiments, two connection electrodes CNE1 and CNE2 are exemplarily described, but embodiments of the present disclosure are not limited thereto. In one or more embodiments of the present disclosure, the first connection electrode CNE1 may not be provided. The second connection electrode CNE2 may be defined as an upper connection electrode, and the first connection electrode CNE1 may be defined as a lower connection electrode.

The second connection electrode CNE2 may be connected to the first connection electrode CNE1 through a second contact hole CNT2 passing through the fifth insulating layer 50. The second connection electrode CNE2 may be electrically connected to the transistor 100PC through the first connection electrode CNE1.

A sixth insulating layer 60 may be arranged on the fifth insulating layer 50. In one or more embodiments, the sixth insulating layer 60 may be a single-layer organic layer, but embodiments of the present disclosure are not limited thereto. A light-emitting element LD may be arranged on the sixth insulating layer 60. In one or more embodiments, the sixth insulating layer 60, which is an insulating (e.g., electrically insulating) layer in contact with and supporting the light-emitting element LD, may be described as a base insulating (e.g., electrically insulating) layer.

The second connection electrode CNE2 may pass through the sixth insulating layer 60. The second connection electrode CNE2 may include a first conductive layer CNE2-1 and a second conductive layer CNE2-2 arranged on the first conductive layer CNE2-1 and having a material different from that of the first conductive layer CNE2-1. In one or more embodiments, the first conductive layer CNE2-1 may include a metal, and the second conductive layer CNE2-2 may include a metal oxide.

As illustrated in FIG. 2D, the second conductive layer CNE2-2 may have a thickness greater than that of the first conductive layer CNE2-1. The second conductive layer CNE2-2 may be formed or arranged by a process different from a process of the first conductive layer CNE2-1. A more detailed description thereof will be provided herein.

On a plane (e.g., in plan view), the second conductive layer CNE2-2 may have a smaller area than that of the first conductive layer CNE2-1. If (e.g., when) viewed on a plane (e.g., in plan view), the second conductive layer CNE2-2 may be arranged inside the first conductive layer CNE2-1.

A width W1 measured at an upper surface US of the second conductive layer CNE2-2 may be smaller than a width W2 measured at a lower surface LS of the second conductive layer CNE2-2. This may be because, during an etching process, the upper surface US of the second conductive layer CNE2-2 is more exposed to an etching solution and reacts more actively than the lower surface LS thereof.

Referring again to FIG. 2C, the display element layer DP-LD may include light-emitting elements LD respectively arranged in the first to third light-emitting regions PXA-1, PXA-2, and PXA-3. For example, the light-emitting element LD may include an organic light-emitting material, an inorganic light-emitting material, an organic-inorganic light-emitting material, a quantum dot, a quantum rod, a micro LED, and/or a nano LED. Hereinafter, the light-emitting element LD is exemplarily described as an organic light-emitting element, but embodiments of the present disclosure are not particularly limited thereto.

FIG. 2C illustrates a first light-emitting element LD1, a second light-emitting element LD2, and a third light-emitting element LD3 arranged in the first to third light-emitting regions PXA-1, PXA-2, and PXA-3, respectively. Each of the first to third light-emitting elements LD1, LD2, and LD3 may include a reflective pattern RP, a first electrode AE, a light-emitting unit EU arranged on the first electrode AE, and a second electrode CE. In one or more embodiments, the first electrode AE may be an anode, and the second electrode CE may be a cathode.

Referring to FIGS. 2C and 2D, the reflective pattern RP may be in contact with the upper surface of the sixth insulating layer 60 and the upper surface US of the second connection electrode CNE2. The upper surface US of the second connection electrode CNE2 may be the upper surface US of the second conductive layer CNE2-2.

The upper surface US of the second connection electrode CNE2 may be continuous with or adjacent to an upper surface 60-US of the sixth insulating layer 60, and the upper surface US of the second connection electrode CNE2 and the upper surface 60-US of the sixth insulating layer 60 may substantially form (or define) a single plane. No step difference may be formed between the upper surface US of the second connection electrode CNE2 and the upper surface 60-US of the sixth insulating layer 60, and the single plane may be a flat (e.g., substantially flat) surface. Accordingly, the reflective pattern RP may be arranged on one continuous surface. The arrangement structure of the reflective pattern RP for the sixth insulating layer 60 and the second connection electrode CNE2 may be related to a manufacturing method of the sixth insulating layer 60, and a more detailed description thereof will be provided herein.

Because the upper surface US of the second connection electrode CNE2 forms a flat (e.g., substantially flat) surface with the upper surface 60-US of the sixth insulating layer 60, the reflective pattern RP arranged on the flat (e.g., substantially flat) surface may have a substantially uniform thickness and a flat (e.g., substantially flat) shape (e.g., a plate shape (e.g., in a form of plates)). Accordingly, the reflective pattern RP may have an overall substantially uniform amount of reflection, and light reflected from the reflective pattern RP may be reflected in substantially the same direction regardless of the region. The fact that the light is reflected in substantially the same direction refers to that the light is radiated in substantially the same form.

As illustrated in FIGS. 2B and 2C, although the second connection electrode CNE2 overlaps a corresponding region among the first to third light-emitting regions PXA-1, PXA-2, and PXA-3, it may not affect the operation of the light-emitting element LD. The region in which the second connection electrode CNE2 is arranged may also correspond to a resonance region of the reflective pattern RP to be described in more detail in one or more embodiments. Because the occupied area of the light-emitting element LD may be set or predetermined regardless of the position of the second connection electrode CNE2, the areas of the first to third light-emitting regions PXA-1, PXA-2, and PXA-3 may be increased.

The reflective pattern RP may be to reflect source light generated from the first to third light-emitting elements LD1, LD2, and LD3 toward the front surface of the display panel DP. A reflective layer RL may include any one of silver (Ag), magnesium (Mg), copper (Cu), aluminum (AI), platinum (Pt), or gold (Au) having high reflectance.

Referring to FIG. 2C, the display element layer DP-LD may include at least one passivation layer 70 arranged on the sixth insulating layer 60. The at least one passivation layer 70 may be arranged between the reflective pattern RP and the second electrode CE. The passivation layer 70 may include an inorganic layer.

The passivation layer 70 may have a different stacked structure depending on the first to third light-emitting regions PXA-1, PXA-2, and PXA-3. The passivation layer 70 having such a structure may affect resonance distances RD of the first to third light-emitting elements LD1, LD2, and LD3. The resonance distance RD may be defined as a distance between the upper surface of the reflective pattern RP and the lower surface of the second electrode CE. The resonance region may be an effective or suitable reflective region of the upper surface of the reflective pattern RP and an effective pr suitable reflective region of the lower surface of the second electrode CE that contribute to a process of converting source light generated from the light-emitting unit EU into emitted light released to the outside. Light output efficiency may increase or enhance as the source light resonates between the effective or suitable reflective region of the upper surface of the reflective pattern RP and the effective or suitable reflective region of the lower surface of the second electrode CE.

Hereinafter, the influence of the passivation layer 70 on the resonance distance RD will be described in more detail. In one or more embodiments, the passivation layer 70 may include a first passivation layer 71, a second passivation layer 72, and a third passivation layer 73. One or more selected from among the first passivation layer 71, the second passivation layer 72, and the third passivation layer 73 may not be arranged in a partial region of the sixth insulating layer 60. The first passivation layer 71 may overlap the first to third light-emitting regions PXA-1, PXA-2, and PXA-3 on the sixth insulating layer 60. The first passivation layer 71 may overlap the non-light-emitting region NPXA of FIG. 2B. However, the second passivation layer 72 may overlap the second light-emitting region PXA-2 and the third light-emitting region PXA-3 and may not overlap the first light-emitting region PXA-1, and the third passivation layer 73 may overlap the third light-emitting region PXA-3 and may not overlap the first light-emitting region PXA-1 and the second light-emitting region PXA-2.

The first passivation layer 71 may be arranged between the first electrode AE of the first light-emitting element LD1 and the reflective pattern RP, and the first passivation layer 71 and the second passivation layer 72 may be arranged between the first electrode AE of the second light-emitting element LD2 and the reflective pattern RP. The first passivation layer 71 to the third passivation layer 73 may be arranged between the first electrode AE of the third light-emitting element LD3 and the reflective pattern RP. Due to the differential structure of the first passivation layer 71 to the third passivation layer 73 as described in one or more embodiments, the resonance distance RD of the first light-emitting element LD1 may become the shortest, and the resonance distance RD of the third light-emitting element LD3 may become the longest.

The first electrode AE of the first light-emitting element LD1 may be arranged on the first passivation layer 71 and connected to the reflective pattern RP of the first light-emitting element LD1 through a contact hole CNT3-1 passing through the first passivation layer 71. The first electrode AE of the second light-emitting element LD2 may be arranged on the second passivation layer 72 and connected to the reflective pattern RP of the second light-emitting element LD2 through a contact hole CNT3-2 passing through the first passivation layer 71 and the second passivation layer 72. The first electrode AE of the third light-emitting element LD3 may be arranged on the third passivation layer 73 and connected to the reflective pattern RP of the third light-emitting element LD3 through a contact hole CNT3-3 passing through the first passivation layer 71 to the third passivation layer 73.

The first electrode AE may include a metal oxide layer OL. The metal oxide layer OL may include indium tin oxide (ITO), indium zinc oxide (IZO), indium gallium zinc oxide (IGZO), zinc oxide (e.g., ZnOₓ, wherein 0<x≤2; e.g., ZnO), indium oxide (e.g., In₂O₃), and/or aluminum-doped zinc oxide (AZO), which facilitates hole injection.

A pixel-defining film PDL may be arranged on the passivation layer 70. A light-emitting opening PDL-OP exposing the first electrodes AE may be defined in the pixel-defining film PDL. The pixel-defining film PDL may be an organic layer. The pixel-defining film PDL may further include a black component, such as a dye and/or pigment, to increase a light-blocking rate.

The light-emitting units EU of the first to third light-emitting elements LD1, LD2, and LD3 and the second electrodes CE of the first to third light-emitting elements LD1, LD2, and LD3 may be arranged on the first electrodes AE and the pixel define layer PDL. The light-emitting units EU may have an integrated shape (e.g., a substantially integrated shape or a monolithic shape), and the second electrodes CE may have an integrated shape (e.g., a substantially integrated shape or a monolithic shape). The light-emitting units EU and the second electrodes CE commonly overlap the first to third light-emitting regions PXA-1, PXA-2, and PXA-3 and the non-light-emitting region NPXA (see FIG. 2B).

In one or more embodiments, the light-emitting unit EU may be to generate a first color light, a second color light, and a third color light as source light. For example, the source light generated from the light-emitting unit EU may include all of the first color light, the second color light, and the third color light.

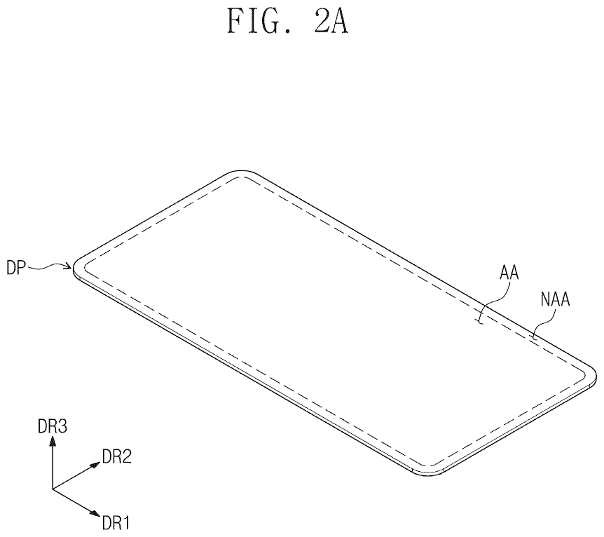

Referring to FIG. 3, the light-emitting unit EU will be described in more detail herein. The light-emitting unit EU may include a hole injection layer PHIL, a first light-emitting layer REML, a first charge generation layer CGL1, a second light-emitting layer BEML, a second charge generation layer CGL2, a third light-emitting layer GEML, and an electron transport layer METL that are sequentially stacked. In one or more embodiments of the present disclosure, the hole injection layer PHIL and the electron transport layer METL may not be provided.

The hole injection layer PHIL may be arranged on the first electrode AE of FIG. 2C. The hole injection layer PHIL may include a hole injection/transport material doped with a P-type (kind) dopant. The electron transport layer METL may include an electron injection/transport material including a metal. Each of the first charge generation layer CGL1 and the second charge generation layer CGL2 may include a first-type (kind) charge generation layer nCGL and a second-type (kind) charge generation layer pCGL that are stacked. The first-type (kind) charge generation layer nCGL may be an n-type (kind) charge generation layer, and the second-type (kind) charge generation layer pCGL may be a p-type (kind) charge generation layer.

The first light-emitting layer REML may be to generate a third color light, the second light-emitting layer BEML may be to generate a first color light, and the third light-emitting layer GEML may be to generate a second color light. The first color light may have a shorter wavelength than the second color light and the third color light. The third color light may have a longer wavelength than the first color light and the second color light.

As described in FIG. 2C, the resonance distances RD of the first to third light-emitting elements LD1, LD2, and LD3 may be set or predetermined to increase or enhance the light output efficiency of desired or suitable light among the first color light, the second color light, and the third color light. Referring to FIG. 2C, the first light-emitting element LD1 having the shortest resonance distance RD among the first to third light-emitting elements LD1, LD2, and LD3 may increase or enhance the light output efficiency of the first color light having the shortest wavelength. The third light-emitting element LD3 having the longest resonance distance RD among the first to third light-emitting elements LD1, LD2, and LD3 may increase or enhance the light output efficiency of the third color light having the longest wavelength.

As a result, although the first color light, the second color light, and the third color light are generated in each of the first to third light-emitting elements LD1, LD2, and LD3, the first color light may be emitted as primary light in the first light-emitting region PXA-1, the second color light may be emitted as primary light in the second light-emitting region PXA-2, and the third color light may be emitted as primary light in the third light-emitting region PXA-3.

A thin film encapsulation layer TFE may be arranged on the second electrode CE. The thin film encapsulation layer TFE may protect the display element layer DP-LD from moisture, oxygen, and/or foreign substances, such as dust particles. The thin film encapsulation layer TFE may include at least one inorganic film (hereinafter, “inorganic encapsulation film”). In one or more embodiments, the thin film encapsulation layer TFE may further include at least one organic film (hereinafter, “organic encapsulation film”). The thin film encapsulation layer TFE may include an inorganic encapsulation layer, an organic encapsulation layer, and an inorganic encapsulation layer, which are sequentially stacked, but layers constituting the thin film encapsulation layer TFE are not limited thereto.

A color filter layer CFL may be arranged on the thin film encapsulation layer TFE. The color filter layer CFL may include a first color filter CF1 corresponding to the first light-emitting region PXA-1, a second color filter CF2 corresponding to the second light-emitting region PXA-2, and a third color filter CF3 corresponding to the third light-emitting region PXA-3. In one or more embodiments, the color filter layer CFL may further include a light-blocking pattern. The first color filter CF1 may be to transmit the first color light, which is primary light, among the first color light, the second color light, and the third color light generated from the first light-emitting element LD1 and blocks or reduces (or absorbs) the second color light and the third color light, which are not primary light. In a similar manner, the second color filter CF2 may be to selectively transmit the second color light, as primary light, among the first color light, the second color light, and the third color light generated from the second light-emitting element LD2, and the third color filter CF3 may be to selectively transmit the third color light, as primary light, among the first color light, the second color light, and the third color light generated from the third light-emitting element LD3.

Each of the first color filter CF1, the second color filter CF2, and the third color filter CF3 may include a polymer photosensitive resin and/or a colorant. In the present disclosure, the colorant may include a pigment and/or a dye. A red colorant may include a red pigment and/or a red dye, a green colorant may include a green pigment and/or a green dye, and a blue colorant may include a blue pigment and/or a blue dye.

The color filter layer CFL may include a planarization layer PZL arranged on the first to third color filters CF1, CF2, and CF3. The planarization layer PZL may include an organic material.

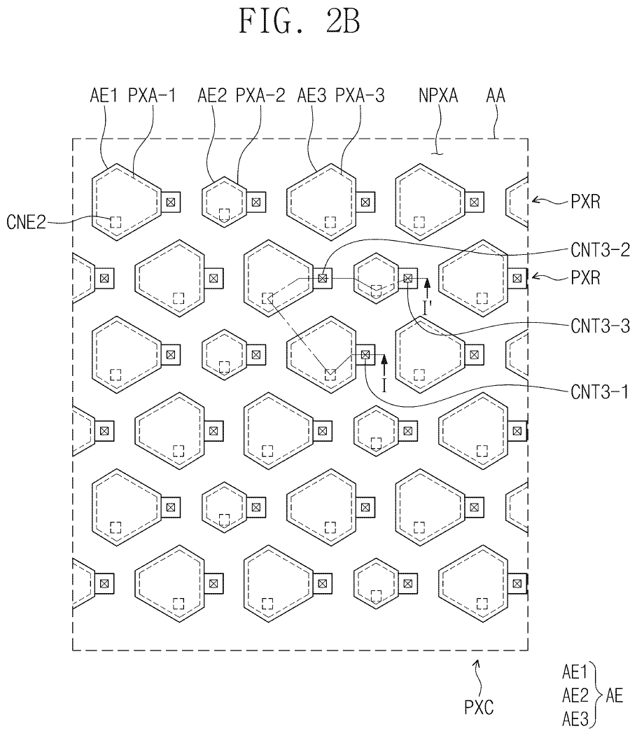

FIGS. 4 to 12 are cross-sectional views illustrating a method for manufacturing a display panel DP according to one or more embodiments of the present disclosure. Hereinafter, more detailed descriptions of substantially the same components as described with reference to FIGS. 2C and 2D may not be provided herein.

As illustrated in FIG. 4, the fifth insulating layer 50 may be formed or arranged on the fourth insulating layer 40. In one or more embodiments, the configuration or arrangement as described with reference to FIG. 2C and arranged between the base layer BS and the fourth insulating layer 40 may be formed or arranged by a suitable manufacturing method for display panels.

The fifth insulating layer 50 may be formed or arranged by a deposition method of an inorganic material. A second contact hole CNT2 may be formed or arranged in the fifth insulating layer 50. After forming or arranging a photoresist on the fifth insulating layer 50, the second contact hole CNT2 may be formed or arranged through exposure, development, and etching processes.

A second connection electrode CNE2 may be formed or arranged on the fifth insulating layer 50. After forming or arranging a first conductive (e.g., electrically conductive) pattern CNE2-1 on the fifth insulating layer 50 through a photolithography process, a second conductive (e.g., electrically conductive) pattern CNE2-2 overlapping the first conductive pattern CNE2-1 may be formed or arranged through a photolithography process.

First, a first conductive (e.g., electrically conductive) layer may be formed or arranged on the fifth insulating layer 50. The first conductive layer may fill the second contact hole CNT2. After forming or arranging a photoresist on the first conductive layer, the first conductive layer may be patterned through exposure, development, and etching processes. Accordingly, the first conductive pattern CNE2-1 may be formed or arranged.

Hereafter, a second conductive (e.g., electrically conductive) layer covering the first conductive pattern CNE2-1 may be formed or arranged on the fifth insulating layer 50. After forming or arranging a photoresist on the second conductive layer, the second conductive layer may be patterned through exposure, development, and etching processes. Accordingly, the second conductive pattern CNE2-2 may be formed or arranged.

The first conductive pattern CNE2-1 and the second conductive pattern CNE2-2 containing different materials may be formed or arranged by two photolithography processes. In one or more embodiments of the present disclosure, the second connection electrode CNE2 may be formed or arranged by a single photolithography process after the first conductive layer and the second conductive layer are continuously formed or arranged.

The second connection electrode CNE2 filling the second contact hole CNT2, for example, the first conductive pattern CNE2-1 may have substantially the same shape as the second contact hole CNT2 within the second contact hole CNT2. The second contact hole CNT2 formed or arranged by a photolithography process may have an upper diameter that is greater than or equal to a lower diameter thereof. Accordingly, the width of the upper portion of the second connection electrode CNE2 arranged within the second contact hole CNT2 may be greater than or equal to the width of the lower portion thereof. However, because the second conductive pattern CNE2-2 does not fill the contact hole, the width of the upper portion of the second conductive pattern CNE2-2, which is more exposed to an etching solution, may be smaller than the width of the lower portion thereof.

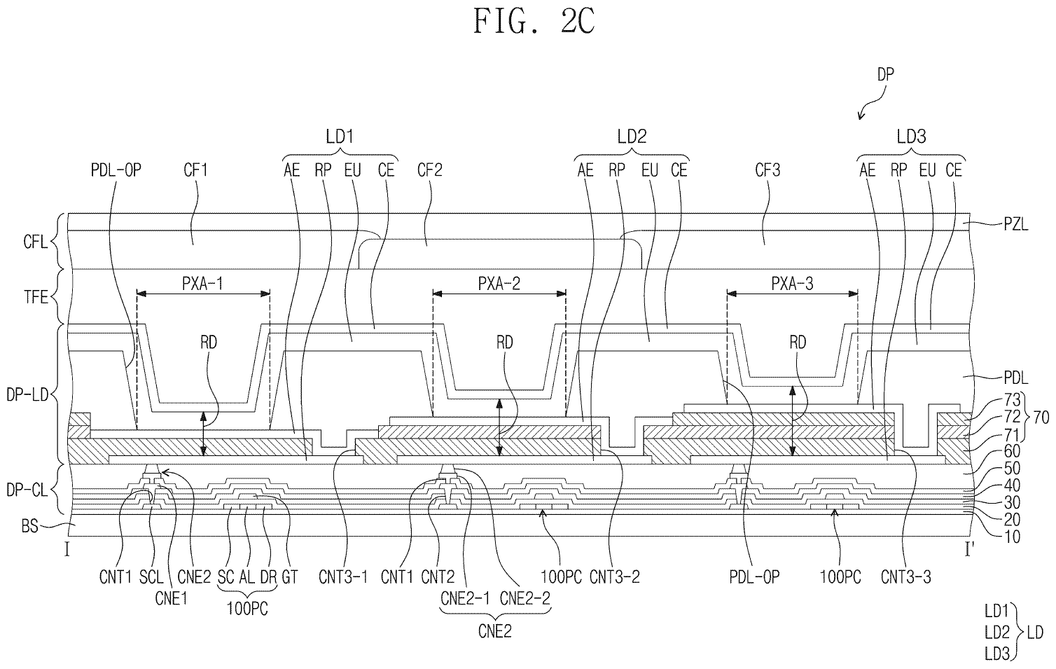

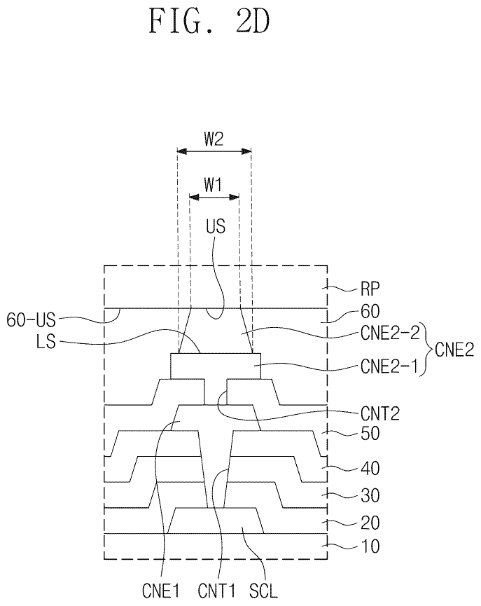

Next, as illustrated in FIG. 5, a preliminary base insulating (e.g., electrically insulating) layer 60-P covering the second connection electrode CNE2 may be formed or arranged on the fifth insulating layer 50. The preliminary base insulating layer 60-P may be formed or arranged by depositing an organic material and/or by inkjet printing and/or coating. FIG. 6 is an image in a state in which the step of FIG. 5 has been performed.

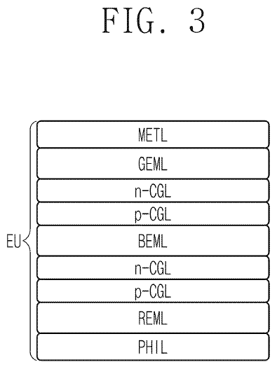

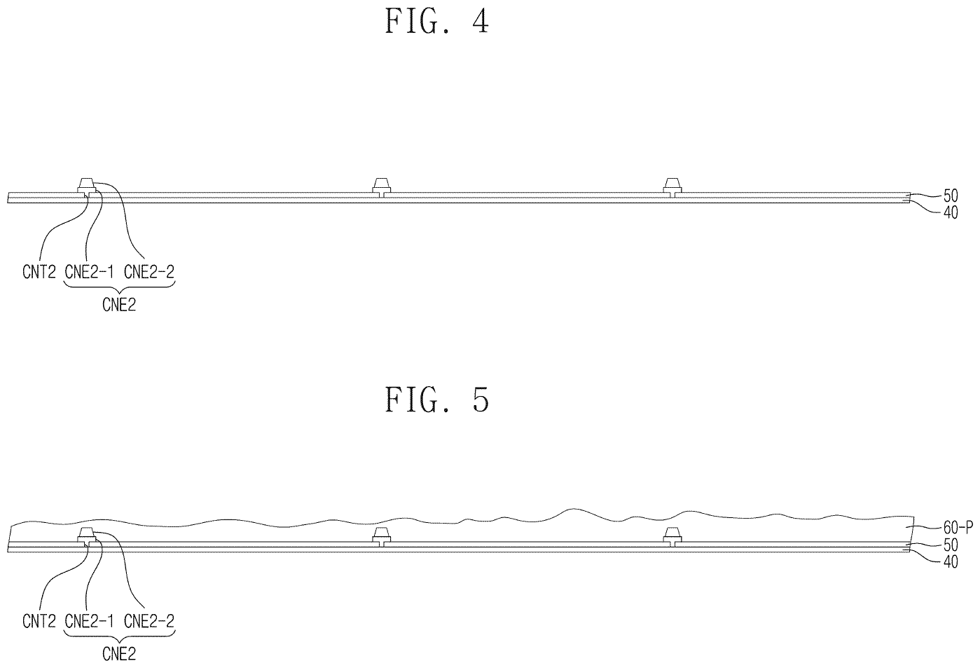

Next, as illustrated in FIG. 7, the preliminary base insulating layer 60-P may be polished to form or arrange a base insulating (e.g., electrically insulating) layer 60 that exposes the upper surface US of the second conductive pattern CNE2-2. The preliminary base insulating layer 60-P may be polished through a chemical-mechanical planarization process. In one or more embodiments, the upper surface US of the second conductive pattern CNE2-2 formed or arranged in the step of FIG. 4 may also be partially polished. FIG. 8 is an image in a state in which the step of FIG. 7 has been performed. The upper surface US of the second conductive pattern CNE2-2 and the upper surface 60-US of the base insulating layer 60 may substantially form or arrange one continuous plane by polishing the preliminary base insulating layer 60-P. The one continuous plane may form or arrange a substantially flat surface. The term “substantially flat surface” refers to a surface formed or arranged through a single polishing process and also refers to a surface on which no step difference is formed.

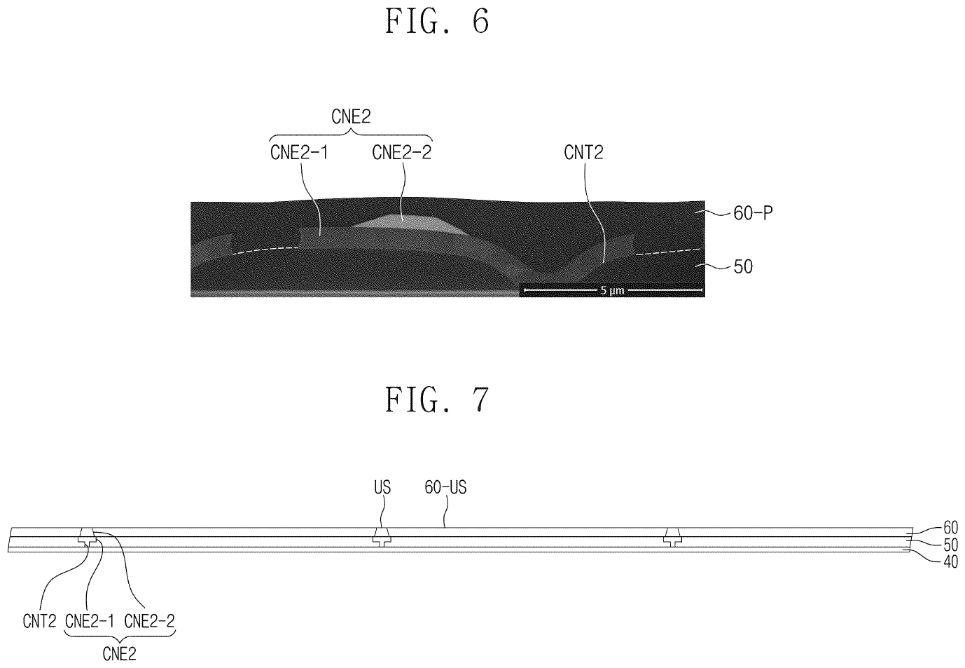

Referring to FIG. 9, a reflective pattern RP may be formed or arranged on the base insulating layer 60. The reflective pattern RP of the first light-emitting element LD1, the reflective pattern RP of the second light-emitting element LD2, and the reflective pattern RP of the third light-emitting element LD3 may be concurrently (e.g., simultaneously) formed or arranged through a photolithography process. Each of the reflective pattern RP of the first light-emitting element LD1, the reflective pattern RP of the second light-emitting element LD2, and the reflective pattern RP of the third light-emitting element LD3 may be connected to a corresponding second connection electrode among the second connection electrodes CNE2.

Hereafter, a first passivation layer 71 covering the reflective pattern RP may be formed or arranged. The first passivation layer 71 may be formed or arranged by depositing an inorganic material. A contact hole CNT3-1 passing through the first passivation layer 71 may be formed or arranged through a photolithography process. A first electrode AE of the first light-emitting element LD1 connected to the reflective pattern RP of the first light-emitting element LD1 through the contact hole CNT3-1 may be formed on the first passivation layer 71 using a photolithography process.

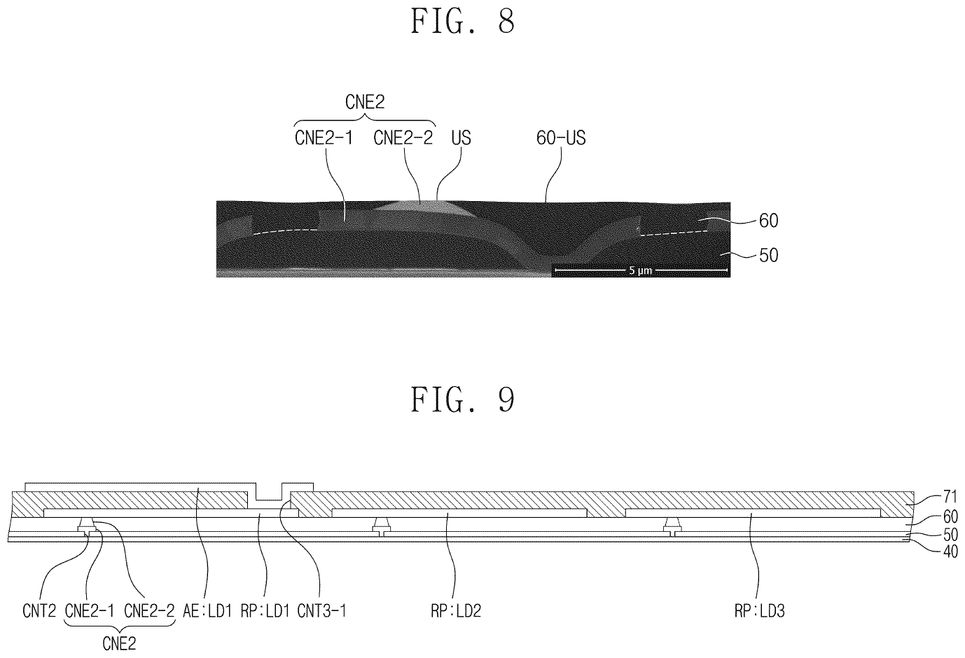

Referring to FIG. 10, a second passivation layer 72 may be formed or arranged so as not to overlap the reflective pattern RP of the first light-emitting element LD1 and so as to overlap the reflective pattern RP of the second light-emitting element LD2 and the reflective pattern RP of the third light-emitting element LD3. A contact hole CNT3-2 passing through the first passivation layer 71 and the second passivation layer 72 may be formed or arranged through a photolithography process. A first electrode AE of the second light-emitting element LD2 connected to the reflective pattern RP of the second light-emitting element LD2 through the contact hole CNT3-2 may be formed or arranged on the second passivation layer 72 using a photolithography process.

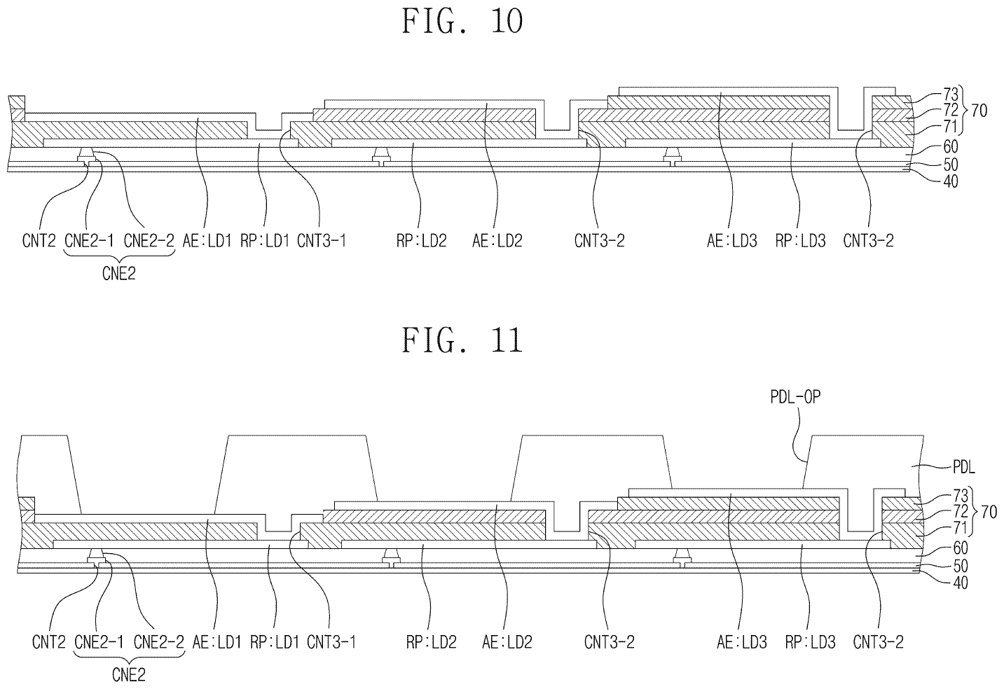

In FIG. 10, the second passivation layer 72 may be described as not overlapping the reflective pattern RP of the first light-emitting element LD1, but embodiments of the present disclosure are not limited thereto. In one or more embodiments, as illustrated in FIG. 11, the second passivation layer 72 may not overlap the opening PDL-OP of the pixel define layer PDL corresponding to the first light-emitting element LD1, and the second passivation layer 72 may partially overlap the reflection pattern RP of the first light-emitting element (LD1). The second passivation layer 72 may not overlap the reflective pattern RP of the first light-emitting element LD1 within a region corresponding to the opening PDL-OP of the pixel define layer PDL corresponding to the first light-emitting element LD1.

A third passivation layer 73 may be formed or arranged so as not to overlap the reflective pattern RP of the first light-emitting element LD1 and the reflective pattern RP of the second light-emitting element LD2 and so as to overlap the reflective pattern RP of the third light-emitting element LD3. A contact hole CNT3-3 passing through the first passivation layer 71, the second passivation layer 72, and the third passivation layer 73 may be formed or arranged through a photolithography process. A first electrode AE of the third light-emitting element LD3 connected to the reflective pattern RP of the third light-emitting element LD3 through the contact hole CNT3-3 may be formed or arranged on the third passivation layer 73 using a photolithography process.

Referring to FIG. 11, a pixel define layer PDL may be formed or arranged. A glass material may be deposited and/or coated to form or arrange an insulating (e.g., electrically insulating) layer, and then openings PDL-OP may be formed or arranged through a photolithography process.

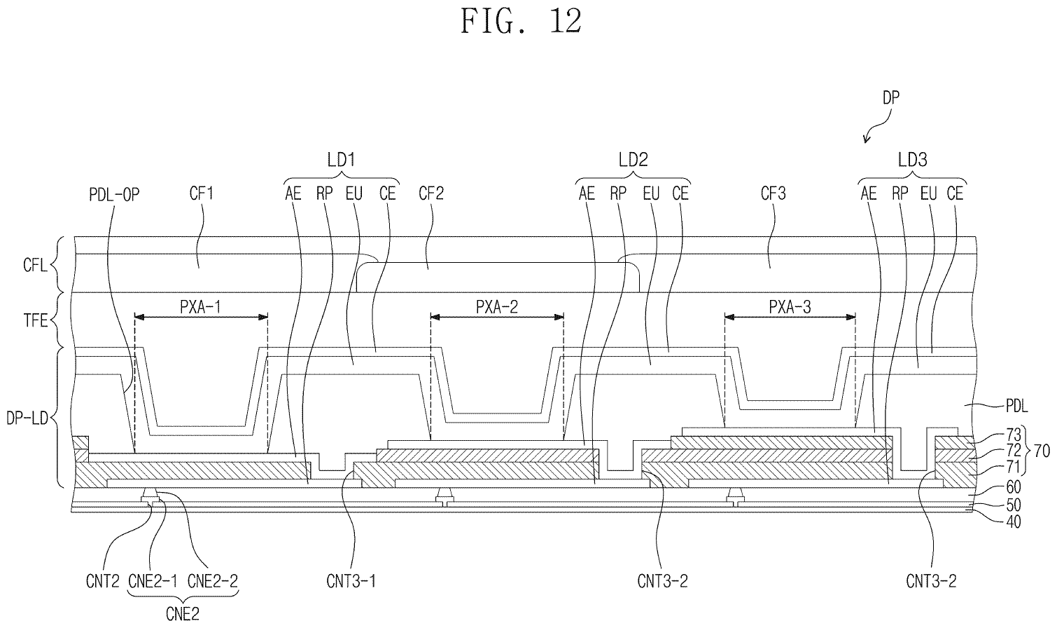

Hereafter, as illustrated in FIG. 12, a light-emitting unit EU and a second electrode CE may be formed or arranged. In one or more embodiments, a color filter layer CFL and a planarization layer PZL may be formed or arranged. These processes may be performed through one or more suitable processes and are not limited to specific processes.

According to one or more embodiments, the connection electrode and the base insulating layer may provide substantially the same plane. Accordingly, the first electrode of the light-emitting element may be arranged on the base insulating layer to overlap the connection electrode. Therefore, the region in which the connection electrode is arranged may be utilized as a light-emitting region. As the area of the light-emitting region increases, the light output efficiency of the display device may be enhanced.

The distance between the reflective pattern and the second electrode may vary depending on the first to third light-emitting elements, and each of the first to third light-emitting elements may improve or enhance the light-emitting efficiency of desired or suitable light among the first to third color lights generated from the light-emitting unit.

A display device, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

Although the above has been described with reference to one or more embodiments of the present disclosure, it should be understood that those skilled in the art or those of ordinary skill in the art will understand that one or more suitable modifications and changes can be made to the present disclosure within the spirit and scope of the appended claims and equivalents thereof, the detailed description of the present disclosure, and the accompanying drawings.

Accordingly, the scope of the present disclosure should not be limited to one or more embodiments/examples, but should be determined by the appended claims described hereinafter as well as the equivalents thereof.

What is claimed is:

1. A display device comprising:
a base layer;
a transistor on the base layer;
a base insulating layer on the transistor;
a connection electrode electrically connected to the transistor, passing through the base insulating layer, and comprising a first conductive layer and a second conductive layer on the first conductive layer and having a material different from a material of the first conductive layer;
a light-emitting element on the base insulating layer and connected to the connection electrode; and
at least one passivation layer on the base insulating layer, and
wherein the light-emitting element comprises:
a reflective pattern in contact with the connection electrode;
a first electrode on the reflective pattern;
a light-emitting unit on the first electrode; and
a second electrode on the light-emitting unit, and
wherein:
the at least one passivation layer is between the first electrode and the reflective pattern;
the first electrode is connected to the reflective pattern through a contact hole passing through the at least one passivation layer;
an upper surface of the connection electrode is continuous with an upper surface of the base insulating layer; and
the upper surface of the connection electrode and the upper surface of the base insulating layer substantially form a single plane.

2. The display device as claimed in claim 1, further comprising a pixel define layer on the first electrode and the at least one passivation layer and having an opening defined therein and exposing at least a portion of the first electrode.

3. The display device as claimed in claim 2, wherein the connection electrode overlaps the opening.

4. The display device as claimed in claim 2, wherein the contact hole overlaps the pixel define layer.

5. The display device as claimed in claim 1, wherein the second conductive layer has a smaller area than an area of the first conductive layer in plan view.

6. The display device as claimed in claim 1, wherein a width measured at an upper surface of the second conductive layer is smaller than a width measured at a lower surface of the second conductive layer.

7. The display device as claimed in claim 1, wherein:
the base insulating layer is a single-layer organic layer; and
the at least one passivation layer comprises an inorganic layer.

8. The display device as claimed in claim 1, wherein:
the first conductive layer comprises a metal; and
the second conductive layer comprises a metal oxide.

9. The display device as claimed in claim 8, wherein the second conductive layer is thicker than the first conductive layer.

10. The display device as claimed in claim 1, wherein:
the light-emitting element comprises a first light-emitting element that is configured to generate a first color light and a second light-emitting element that is configured to generate a second color light having a longer wavelength than the first color light; and
the at least one passivation layer comprises a first passivation layer and a second passivation layer, and
wherein:
the first passivation layer is between the first electrode of the first light-emitting element and the reflective pattern of the first light-emitting element; and
the first passivation layer and the second passivation layer are between the first electrode of the second light-emitting element and the reflective pattern of the second light-emitting element.

11. The display device as claimed in claim 10, wherein the light-emitting unit of the first light-emitting element and the light-emitting unit of the second light-emitting element have an integrated shape.

12. The display device as claimed in claim 1, wherein the light-emitting unit comprises:
a first light-emitting layer configured to generate a first color light;
a first charge generation layer on the first light-emitting layer;
a second light-emitting layer on the first charge generation layer and configured to generate a second color light;
a second charge generation layer on the second light-emitting layer; and
a third light-emitting layer on the second charge generation layer and configured to generate a third color light.

13. The display device as claimed in claim 1, further comprising:
a thin film encapsulation layer arranged to cover the light-emitting element; and
a color filter on the thin film encapsulation layer to overlap the light-emitting element.

14. The display device as claimed in claim 1, further comprising a lower connection electrode electrically connecting the transistor and the connection electrode and arranged below the base insulating layer.

15. The display device as claimed in claim 1, wherein the base layer comprises a glass substrate.

16. An electronic apparatus comprising:
a display device; and
a frame arranged to accommodate the display device,
wherein the display device comprises:
a transistor;
a base insulating layer on the transistor;
a connection electrode electrically connected to the transistor, passing through the base insulating layer, and comprising a first conductive layer and a second conductive layer on the first conductive layer and having a material different from a material of the first conductive layer;
a light-emitting element on the base insulating layer and connected to the connection electrode; and
at least one passivation layer on the base insulating layer,
wherein the light-emitting element comprises:
a reflective pattern;
a first electrode on the reflective pattern;
a light-emitting unit on the first electrode; and
a second electrode on the light-emitting unit, and
wherein:
the at least one passivation layer is between the first electrode and the reflective pattern;
the first electrode is connected to the reflective pattern through a contact hole passing through the at least one passivation layer;
an upper surface of the connection electrode is continuous with an upper surface of the base insulating layer; and
the upper surface of the connection electrode and the upper surface of the base insulating layer substantially form a single plane.

17. The electronic apparatus as claimed in claim 16, wherein the electronic apparatus is a virtual reality (VR) terminal.

18. A method for manufacturing a display device, the method comprising:
forming a first conductive pattern on a base layer;
forming a second conductive pattern comprising a material different from a material of the first conductive pattern on the first conductive pattern;
forming a preliminary base insulating layer to cover the second conductive pattern;
polishing the preliminary base insulating layer to form a base insulating layer that exposes an upper surface of the second conductive pattern;
forming a reflective pattern connected to the second conductive pattern on the base insulating layer;
forming at least one passivation layer covering the reflective pattern on the base insulating layer;
forming a first electrode connected to the reflective pattern through a contact hole passing through the at least one passivation layer on the at least one passivation layer;
forming a light-emitting unit on the first electrode; and
forming a second electrode on the light-emitting unit,
wherein:
an upper surface of the connection electrode is continuous with an upper surface of the base insulating layer; and
the upper surface of the connection electrode and the upper surface of the base insulating layer substantially form a single plane.

19. The method as claimed in claim 18, wherein, in plan view, the second conductive pattern has a smaller area than an area of the first conductive pattern.

20. The method as claimed in claim 18, wherein a width measured at the upper surface of the second conductive pattern is smaller than a width measured at a lower surface of the second conductive pattern.
